(19) United States
(12) Patent Application Publication
(10) Pub. No.: US 2001/0028550 A1
(43) Pub. Date: Oct. 11, 2001

(54) Cooling method and apparatus for electric device

(76) Inventors: Hideaki Miyake, Toyokawa (JP); Yuichi Fukuda, Seto (JP); Takashi Moriyama, Owariasahi (JP); Shigemi Ota, Fijisawa (JP)

Correspondence Address: MATTINGLY, STANGER & MALUR, P.C., 104 EAST HUME AVENUE, ALEXANDRIA, VA, 22301, US

(21) Appl. No.: 09/791,623

(22) Filed: Feb. 26, 2001

(30) Foreign Application Priority Data
Feb. 28, 2000 (JP) 2000-051341

(51) Int. Cl. H05K 7/20

(52) U.S. Cl. 361/695

(57) ABSTRACT

A fan box has a principal inlet side and a principal outlet side disposed opposite to each other, in which sides a plurality of inlets and a plurality of outlets are formed respectively. In the fan box, a plurality of fan units, each of which holds a multiblade fan, are arranged side by side with the axial directions of the multiblade fans oriented in the same direction. Each fan unit has the construction in which a fan inlet is in communication with the inlets through a suction duct and a fan outlet is in communication with the outlets. Check valves are provided on the respective outlets, and when the multiblade fan of a specific fan unit stops operating, the check valve of the outlet corresponding to that multiblade fan is autonomously closed to prevent a reduction in the cooling capacity due to the air flowing back and circulating within the multiblade fan to continue the operation.

### BACKGROUND OF THE INVENTION

The present invention relates to a cooling technology and an information processing technology, and more particularly, to a technology effective for application to forced-air cooling of an information processing unit such as a small server with highly integrated components or other electric devices.

A forced-air cooling technology with fans has generally been used as a cooling system for an electric device, but recently, a multiblade fan of excellent static pressure characteristics is often used to accommodate increase in the packing density of components and reduction in the area for suction and exhaust due to the miniaturization of a housing for an electric device and so forth. Further, for an electric device generating a large amount of heat, it is required to enlarge cooling capacity by providing in parallel a plurality of multiblade fans for connection with a duct.

When a plurality of multiblade fans are provided in parallel for connection with a duct and operated to continuously to increase the cooling capacity, however, there may be caused a technical problem as follows. If a specific multiblade fan stops due to failure or for maintenance, an exhaust pressure produced by the other multiblade fans in the duct causes the air to flow backward from the outlet to the inlet of the standing multiblade fan, and the air flow reaching the inlet is sucked into the inlets of the other operating multiblade fans. As a result, the air flow moves in circles between a space on the inlet side and another space on the outlet side (in the duct) of the cooling apparatus with a large loss of cooling capacity.

As a conventional cooling technology for an electric device, for example, JP-A-5-21978 discloses a technology for avoiding operation stopping of an electric device to be cooled due to failure of a cooling fan by providing two, active and standby systems of fans and power supplies to operate the standby system fan when the active system fan fails.

According to the technology disclosed by JP-A-5-21978, however, only one of the active and standby system fans operates together with the associated power supply at a point of time. Thus, no consideration is given to the above-mentioned technical problem of a large reduction in the cooling capacity which may be caused when a plurality of multiblade fans are continuously operated to increase the cooling capacity.

### SUMMARY OF THE INVENTION

It is an object of the present invention to provide a cooling technology which can prevent a large reduction in cooling capacity due to stopping of a specific multiblade fan in the collective configuration of a plurality of multiblade fans for continuous operation.

It is another object of the invention to provide a cooling technology which allows replacement of any multiblade fan in a cooling apparatus having a plurality of multiblade fans operating continuously, without largely lowering the cooling capacity of the cooling apparatus.

It is still another object of the invention to provide a cooling technology which allows replacement of any multiblade fan in a cooling apparatus having a plurality of multiblade fans operating continuously, irrespective of the physical orientation of installation of the cooling apparatus.

It is yet another object of the invention to provide an information processing unit which can realize the miniaturization of its entire housing inclusive of a cooling apparatus.

It is further object of the invention to provide an information processing unit which can operate uninterruptedly irrespective of partial failure or maintenance of a cooling apparatus.

A cooling method according to the invention comprises the steps of providing a plurality of fans side by side at predetermined intervals in the axial direction of their rotors, each of which fans has its inlet and outlet opened respectively in the axial and the circumferential direction of its rotor, connecting the outlet of each fan with a partition which separates the inlet side from the outlet side of each fan, providing a check valve in at least one of an inlet passage and an outlet passage for each fan to close the inlet passage or the outlet passage to autonomously prevent backflow of the air from the outlet to the inlet when the fan stops operating, and continuously operating the plurality of fans.

A cooling apparatus according to the invention includes a plurality of fans which are arranged side by side in the axial direction of their rotors and continuously operated, each fan having its inlet and outlet opened respectively in the axial and the circumferential direction of its rotor, a check valve which is provided in at least one of an inlet passage and an outlet passage for each fan to close the inlet passage or the outlet passage to autonomously prevent backflow of the air from the outlet to the inlet when the fan stops operating, and a partition separating the inlet side from the outlet side of each fan.

A cooling apparatus according to the invention comprise:

a fan box having a principal inlet side and a principal outlet side opposed to each other, in which sides a plurality of inlet openings and outlet openings are provided respectively;

fan units attachable to/detachable from the fan box and each holding fans for continuous operation; and

check valves each provided in at least one of the inlet openings and the outlet openings to autonomously prevent backflow of the air from the outlet openings to the inlet openings when a fan stops operating.

An information processing unit according to the invention comprises at least an external storage and a power supply mounted within a housing, wherein provided in the housing is a cooling apparatus including:

a plurality of fans which are arranged side by side in the axial direction of their rotors and continuously operated, each fan having its inlet and outlet opened respectively in the axial and the circumferential direction of its rotor, a check valve provided in at least one of an inlet passage and an outlet passage for each fan to close the inlet passage or the outlet passage to autonomously prevent backflow of the air from the outlet to the inlet when the fan stops operating, and a partition separating the inlet side from the outlet side of each fan.

An information processing unit according to the invention comprises at least an external storage and a power supply mounted within a housing, wherein provided in the housing is a cooling apparatus including:

a fan box having a principal inlet side and a principal outlet side opposed to each other, in which sides a plurality of inlet openings and outlet openings are provided respectively;

fan units attachable to/detachable from the fan box and each holding fans for continuous operation; and

check valves each provided in at least one of the inlet openings and the outlet openings to autonomously prevent backflow of the air from the outlet openings to the inlet openings when a fan stops operating.

### BRIEF DESCRIPTION OF THE DRAWINGS

FIG. 1 is an exploded perspective view for showing an example of a configuration of a cooling apparatus according to an embodiment of the invention;

FIGS. 2A and 2B are perspective views, as viewed in opposite directions to each other, of a multiblade fan held in a fan unit which constitutes the cooling apparatus according to the embodiment of the invention;

FIG. 3 is a perspective view for showing an example of mounting relationship between the cooling apparatus according to the embodiment of the invention, which is in the state that its assembling has been completed, and a cooling duct;

FIG. 4 is a perspective view for showing the assembled state in the opposite direction to that of FIG. 3;

FIG. 5 is a perspective view for showing an example of a check valve constituting the cooling apparatus according to the embodiment of the invention;

FIG. 6 is a perspective view for showing a variation of the check valve constituting the cooling apparatus according to the embodiment of the invention;

FIG. 7 is an exploded perspective view for showing an example of a configuration of an information processing unit according to an embodiment of the invention together with the cooling apparatus;

FIG. 8 is a perspective view for showing the example of the configuration of the information processing unit according to the embodiment in its assembled state;

FIG. 9 is a conceptual diagram for schematically showing a variation of mounting of the check valve on the cooling apparatus according to the embodiment of the invention; and

FIG. 10 is a conceptual diagram for showing and comparing an example of an operating state and that of a partially standing-still state of the cooling apparatus according to the embodiment of the invention.

### DETAILED DESCRIPTION OF THE PREFERRED EMBODIMENTS

Now, an embodiment of the present invention will be described in detail with reference to the drawings.

A cooling apparatus 10 according to this embodiment comprises a fan box 20 and a plurality of fan units 30, each of which is detachably contained in the fan box 20 and holds a multiblade fan 50.

The fan box 20 has a plurality of inlets 21a and a plurality of outlets 22a formed in a principal inlet side 21 and a principal outlet side 22, respectively, and these principal sides are opposed to each other in the direction intersecting that for attachment/detachment of the fan units 30.

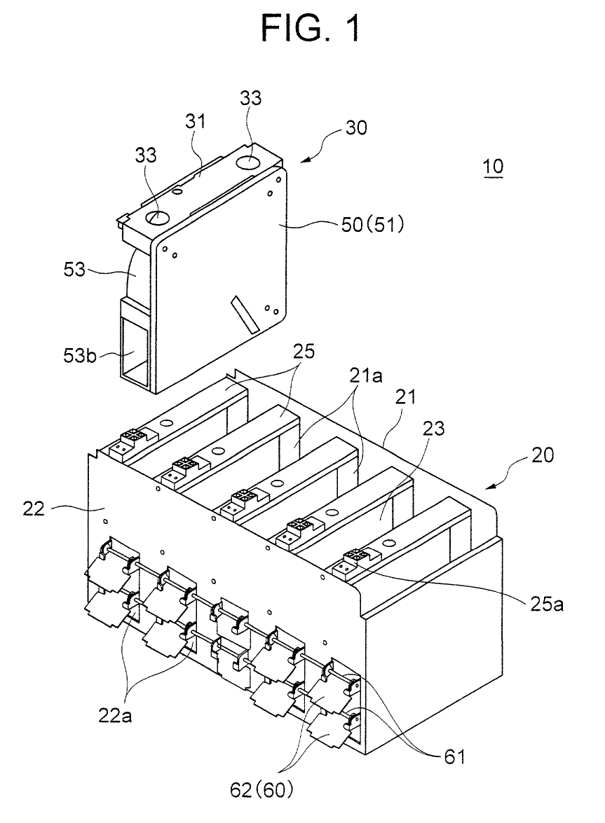

On the end for attachment/detachment of the fan unit 30 in the fan box 20, a plurality of terminal boards 25 are placed at intervals conforming to those of the fan units and in the direction in which the fan units 30 are arrayed, so that each terminal board is situated to face the side of each of the fan units 30. Each of the terminal boards 25 has a feeding connector 25a mounted thereon for connection with a power supply which is not shown in FIG. 1. The space below each of the terminal boards 25 forms a suction duct 23 in communication with each of the plurality of inlets 21a.

As illustrated in detached state in FIG. 1, the fan unit 30 according to this embodiment consists of a fan holder 31 and a multiblade fan 50 held on the undersurface of the fan holder 31. In addition, a feeder cable laying groove 32 and a working hole 33 for attachment/detachment are provided in the top surface of the fan holder 31.

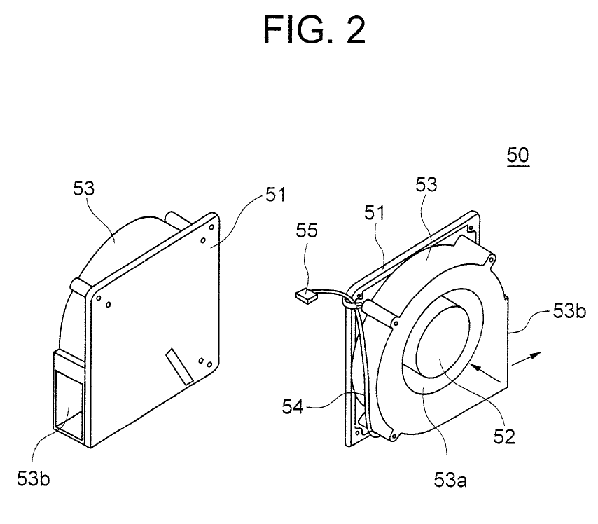

FIGS. 2A and 2B are perspective views taken from the directions opposite to each other for showing the multiblade fan 50 held in each of the fan units 30. The multiblade fan 50 according to this embodiment comprises a mounting base 51, a rotor 52, a fan housing 53, a feeder cable 54, and a feeding connector 55. The rotation of the rotor 52 allows the air taken in through a fan inlet 53a provided in the axial side of the fan housing 53 to be discharged through a fan outlet 53b provided in the circumferential direction of the fan housing 53.

In the fan unit 30, the multiblade fan 50 is fixed to the fan holder 31 through the mounting base 51, the feeder cable 54 is pulled laterally out of the fan holder 31 on the terminal block 25 side through the feeder cable laying groove 32, and the feeding connector 55 at the end of the feeder cable is connected with the feeding connector 25a of the fan unit 30.

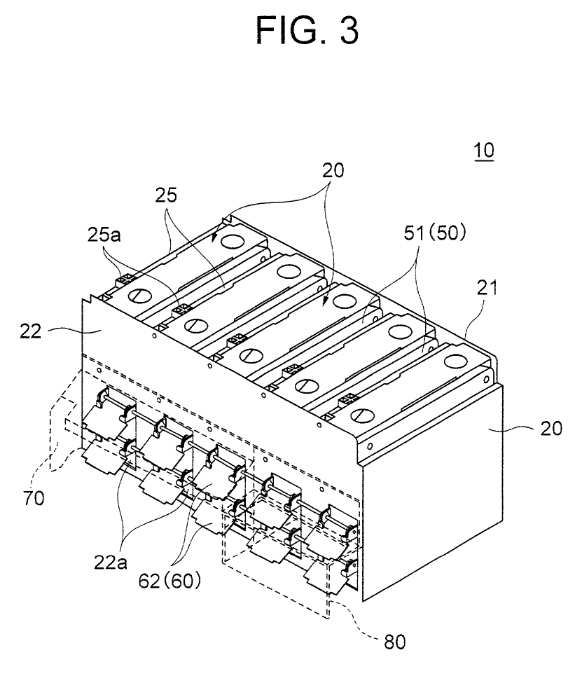

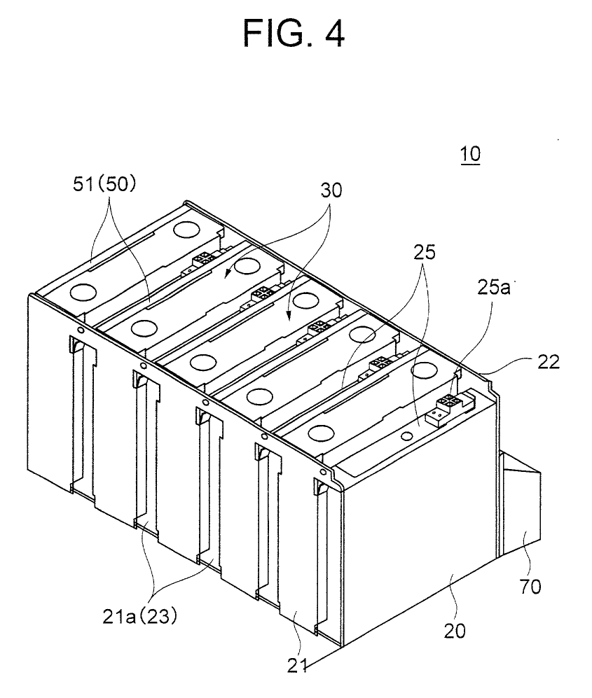

In the assembled state illustrated in FIGS. 3 and 4, the multiblade fan 50, which is held in each of the fan units 30 and then attached to the fan box 20, is secured in the position in which the fan inlet 53a is in communication with each of the inlets 21a through the suction duct 23 and the fan outlet 53b is conformably in communication with each of the outlets 22a.

As described above, the cooling apparatus 10 according to this embodiment has the construction that the plurality of fan units 30 are collectively mounted in the fan box 20 at predetermined intervals with their multiblade fans 50 being in a position for orienting the axes of the rotors 52 in the same direction. Accordingly, it is possible to realize a large forced-air cooling capacity from the collective arrangement of the plurality of multiblade fans 50 continuously operating while requiring a relatively small volume occupied by the cooling apparatus 10.

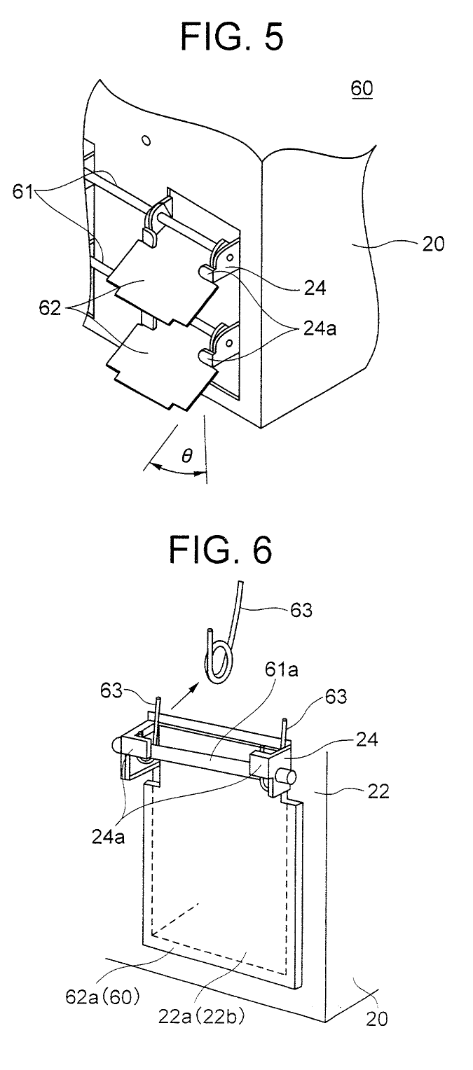

In the cooling apparatus 10 according to this embodiment, a check valve 60 is provided for each of the plurality of outlets 22a in the fan box 20, as illustrated in FIG. 5.

The check valve 60 is comprised of a plurality of valve elements 62 which are supposed at their opposite ends through common rocking shafts 61 swingably about bearing pieces 24 respectively provided for the openings of the outlets 22a in the fan box 20. Each of the valve elements 62 is made of, for example, lightweight resin having a sufficient rigidity to close the outlet 22a. In the case of this embodiment, the bearing piece 24 has a stopper 24a formed thereon for limiting the opening angle θ of each of the plurality of valve elements 62 to an acute angle.

This construction allows the check valve 60 in this embodiment to move the plurality of valve elements 62 in the direction of closing the outlet 22a by means of their own weights or by means of a dynamic pressure of the air flow which is about to reverse from the outside of the principal outlet side 22 into to the outlet 22a (hereinafter referred to as reverse air flow) or a dynamic pressure of the reverse air flow to prevent the backflow, even when the fan box 20 is in any position. In FIG. 1, the check valve 60 provided for the third outlet 22a from the right is illustrated in the closed state.

Further, as the construction is such that the plurality of valve elements 62 are used to open and close each outlet 22a, each valve element 62 may be made lighter while keeping a sufficient rigidity, as compared with the case where a single valve element is used. This results in improving the responsibility of each valve elements 62 when closing under a dynamic pressure of the reverse air flow to realize a reliable closing operation.

An example of the operation of the cooling apparatus 10 according to this embodiment will be described below.

A cooling duct 70 and a cooling duct 80 are connected with the outlets 22a on the principal outlet side 22 of the fan box 20 as necessary. These cooling ducts 70 and 80 are provided to guide the exhaust flow discharged through the outlets 22a to an object to be cooled.

Then, the plurality of fan units 30 are first attached to the fan box 20 as shown in FIGS. 3 and 4. This allows the fan outlet 53b of the multiblade fan 50 in each of the fan units 30 to be conformably fixed to the outlet 22a of the fan box 20 and the fan inlet 53a to be in communication with each of the inlets 21a of the fan box 20 through the suction duct 23 below the terminal block 25. The feeder cable 54 pulled out through the feeder cable laying groove 32 of the fan unit 30 is connected through the feeding connector 55 at its end with the feeding connector 25a on the terminal board 25 of the fan box 20, and thus the multiblade fan 50 held in the fan unit 30 is supplied with electric power into operating state.

Thus, within the fan box 20, the continuous operation of the multiblade fan 50 of each of the fan units 30 causes the air outside the principal inlet side 21 to be taken in through an adjacent inlet 21a, the suction duct 23, and the fan inlet 53a and then, after pressurization, to be discharged through the fan outlet 53b, the outlet 22a, and the check valve 60 to the space outside the principal outlet side 22 (within the cooling ducts 70 and 80). A continuously operating state of the plurality of multiblade fans 50 is shown in the left part of FIG. 10.

In this FIG. 10, however, the check valve 60 and other components are simplistically depicted.

Thus, the air pressure P2 of the space outside the principal outlet side 22 (in this case, the space within the cooling ducts 70 and 80) is made larger than the air pressure P1 outside the principal inlet side 21.

When the multiblade fan 50 of some fan unit 30 is stopped due to failure or when the power supply to the multiblade fan 50 of the fan unit 30 is stopped by removing the fan unit 30 from the fan box 20 for maintenance or the like, the exhaust flow passing through the check valve 60 is also stopped. Thus, a pressure difference between the above-mentioned air pressures P1 and P2 causes a reverse air flow flowing inside the stopped multiblade fan 50, and if left as it is, the reverse air flow may reach the space outside the principal inlet side 21 through the corresponding inlet 21a and then it may be taken in through the other inlets 21a to form an air flow circulating within the fan box 20 and to reduce the cooling capacity due to a drop in the air pressure P2 at the principal outlet side 22 (this situation is shown in the right part of FIG. 10).

On the contrary, since this embodiment has the check valve 60 provided for the outlet 22a, the plurality of valve elements 62 of the check valve 60 for the outlet 22a corresponding to the fan unit 30 are autonomously closed under their own weights and a dynamic pressure of the above-mentioned reverse air flow to block the reverse air flow, so that any circulation of the reverse air flow and any reduction in the cooling capacity due to a drop in the air pressure P2 at the principal outlet side 22 can be prevented.

As described above, the cooling apparatus 10 according to this embodiment, even when the multiblade 50 of a fan unit 30 is stopped due to failure or any fan unit 30 is detached from the fan box 20 for maintenance, thanks to the function of the check valve 60 autonomously blocking the reverse air flow, can prevent any circulation of the reverse air flow at the outlet 22a corresponding to the fan unit 30 and any reduction in cooling capacity due to a drop in the air pressure P2 at the principal outlet side 22.

Therefore, for example, if some more fan units 30 are installed to provide the cooling apparatus 10 with a more cooling capacity than required, any shutdown of a device to be cooled which is not shown in the drawings can be avoided even when a multiblade fan 50 fails during the operation and the cooling capacity is reduced. The maintenance operation can be freely performed by detaching/attaching any fan unit 30 while a device to be cooled which is not shown in the drawings is kept operating.

For example, when the cooling apparatus 10 according to this embodiment is applied as cooling means for an information processing unit such as a server which is designed for long-term nonstop operation, the information processing unit such as a server can operate for a long term without interruption.

It should be appreciated that the check valve 60 is not limited to the above-mentioned configuration wherein its valve elements are autonomously closed under their own weights or a dynamic pressure of reverse air flow as illustrated in FIG. 5 but it may have another configuration wherein the valve elements are autonomously closed under the force of a spring as illustrated in FIG. 6. More specifically, in the example shown in FIG. 6, a coil spring 63 is attached to the rocking shaft 61 with one end of the coil spring 63 in contact with the stopper 24a and the other end in contact with a valve element 62a, and the opening force at the ends of the coil spring 63 continuously pushes the rocking valve element 62a in the direction for closing it. Incidentally, the force of the coil spring 63 is set to such a value that the valve element 62a may be easily opened under a dynamic pressure of exhaust flow discharged through the outlet 22a during the operation of the multiblade fan 50 and the valve element 62a in any position may be closed against its own weight or rotary resistance by friction of the rocking shaft 61 in the absence of a dynamic pressure of exhaust flow.

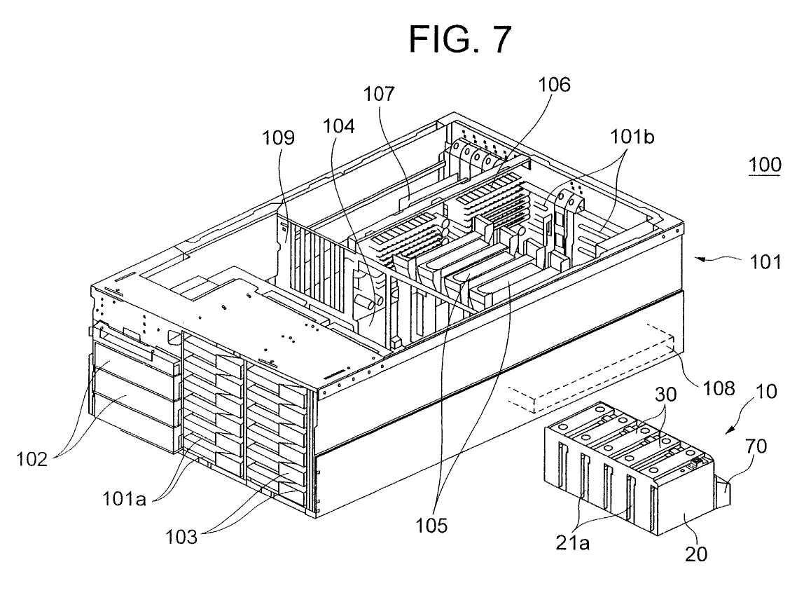

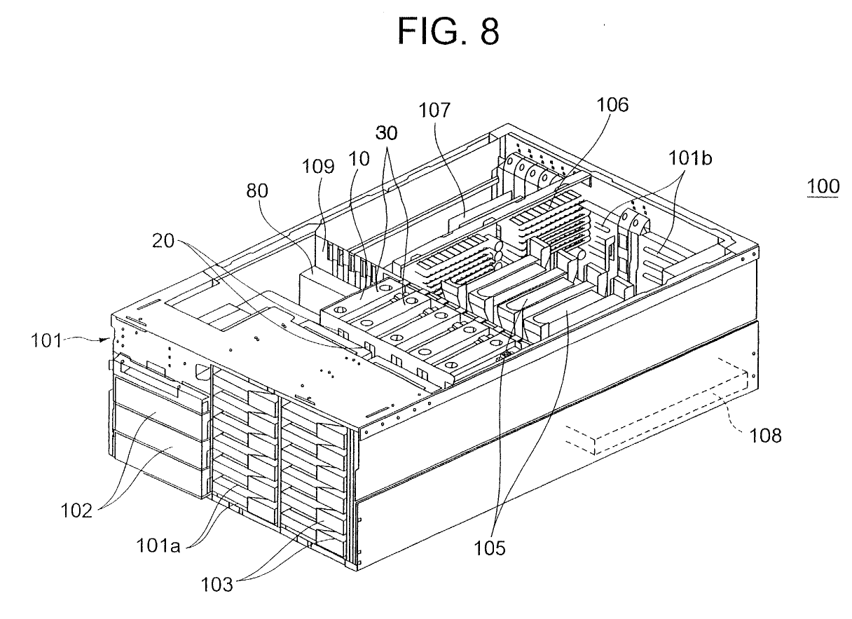

Next, the configuration of an information processing unit which adopts the above-mentioned cooling apparatus according to this embodiment will be described with reference to FIGS. 7 and 8. It should be appreciated that a housing cover, which is not shown in the drawings, is removed to show the inside of a housing.

As illustrated in FIGS. 7 and 8, the information processing unit 100 according to this embodiment is comprised of the housing 101, a plurality of fixed disk devices 102, 103 which are detachably mounted into openings at one end of the housing 101 from outside, a mother board 104, a plurality of processor modules 105, memory modules 106, and I/O control modules 107 which are mounted on the mother board 104, and a power module 108 which is mounted under the mother board 104.

In the housing 101, ventilation gaps 101a are provided between the plurality of fixed disk devices 102, 103 which are detachably mounted from outside and ventilation slits 101b are provided on the opposite end of the housing where the plurality of processor modules 105 are located.

Each of the processor modules 105 has a microprocessor which is not shown in the drawings and performs necessary information processing operations under the control of a program loaded into the main memory, that is, the memory modules 106.

The I/O control modules 107 operate under the control of the processor modules 105 to control the data input/output operations for the plurality of fixed disk devices 102 and fixed disk devices 103, any external information network which is not shown in the drawings, and the information input/output operations for user interfaces such as a display, a keyboard, and a mouse.

The power module 108 supplies operating power to the plurality of fixed disk devices 102 and fixed disk devices 103, the mother board 104, the plurality of processor modules 105, memory modules 106, and I/O control modules 107, and the multiblade fans 50 of the cooling apparatus 10 as described above.

In the information processing unit 100 according to this embodiment, a duct fixation frame 109 is provided in the middle of the housing 101, and the cooling apparatus 10, to which the cooling duct 70 and the cooling duct 80 are attached on the principal outlet side 22 as illustrated in FIGS. 3 and 4, is mounted on the information processing unit 100 as shown in FIG. 8.

Namely, the cooling apparatus 10 for this embodiment is mounted in the middle of the housing 101 with three left outlets 22a in the principal outlet side 22 connected with the cooling duct 70, two right outlets 22a connected with the cooling duct 80, the principal outlet side 22 facing the processor modules 105, and the principal inlet side 21 facing the fixed disk devices 102 and the fixed disk devices 103 as illustrated in FIG. 3, and the cooling duct 70 and the cooling duct 80 are supported with the duct fixation frame 109.

In this mounted state of the cooling apparatus 10, as illustrated in FIG. 8, the working hole 33 for attachment/detachment in each of the plurality of fan units 30 constituting the cooling apparatus 10 is exposed to outside when the housing cover which is not shown in the drawings is removed, so that the attachment/detachment operation of the fan unit 30 can be easily performed.

As described above, the cooling apparatus 10 according to this embodiment has the configuration that the plurality of fan units 30 are collectively arranged in the fan box 20 and thus it can provide a larger cooling capacity through the collective arrangement of the plurality of multiblade fans 50 in a small volume of apparatus, resulting in a reduction in volume ratio of the cooling apparatus 10 which occupies the inside space of the housing 101 of the information processing unit 100 as well as a downsizing of the housing 101.

The cooling duct 70 guides the air flow discharged through the plurality of outlets 22a to the power module 108 located below the mother board 104, and the cooling duct 80 guides the air flow discharged through the outlets 22a to the area where the processor modules 105 and the memory modules 106 are located and to the area where the I/O control modules 107 are located.

For the cooling duct 70 and the cooling duct 80, the cooling capacity of each cooling duct can be arbitrarily changed by varying the number of outlets 22a belonging to each of the cooling ducts 70 and 80.

It should be appreciated that according to this embodiment, the number of fan units 30 in the cooling apparatus 10, that is, the cooling capacity of the cooling apparatus 10 is set to a relatively large value as compared with the amount of heat generated in the housing 101 of the information processing unit 100, which can continuously operate without any trouble even when, for example, the multiblade fan 50 of any one fan unit 30 is stopped.

An example of the operation of the information processing unit 100 according to this embodiment will be described below.

When the information processing unit 100 is turned on, the plurality of multiblade fans 50 of the fan units 30 in the cooling apparatus 10 are started and the air within the housing 101 is taken in through the plurality of inlets 21a in the principal inlet side 21 of the cooling apparatus 10 and then discharged into the cooling duct 70 and the cooling duct 80 near the principal outlet side 22.

Thus, in the housing 101 of the information processing unit 100, an air flow, which flows into the housing 101 through the ventilation gaps 101a between the plurality of fixed disk devices 102, 103, passes through the power module 108, the mother board 104, and the plurality of processor modules 105, the memory modules 106, and the I/O control modules 107, and then goes out through the ventilation slits 101b on the opposite side, is steadily formed and this air flow functions to cool the plurality of fixed disk devices 102, 103, the power module 108, the mother board 104, the processor modules 105, the memory modules 106, and the I/O control modules 107.

If the multiblade fans 50 of some excess fan units 30 in the cooling apparatus 10 are stopped during the operation of the information processing apparatus 100, the operation of the check valve 60 can restrain any possible reduction in cooling capacity of the cooling apparatus 10 to that resulting from the stoppage of the excess multiblade fans 50, and this can avoid a reduction in cooling capacity of the whole cooling apparatus 10 which may result from any circulation of the exhaust flow due to a failing fan unit 30.

It should be also appreciated that which fan unit includes a failing multiblade fan 50 can be easily determined by monitoring the power module 108 to check for normal power supply to each of the plurality of feeding connectors 25a provided on the terminal boards 25 of the cooling apparatus 10.

When any fan unit 30 is replaced during the maintenance operation, the backflow prevention action of the check valve 60 with respect to the detached fan unit 30 allows the fan unit 30 to be replaced while the information processing unit 100 is operating without any loss in cooling capacity of the whole cooling apparatus 10.

When the check valve 60 of the cooling apparatus 10 has the configuration shown in FIG. 5, the information processing unit 100 can be operated in a position where it is turned around the flowing direction of any suction flow and exhaust flow produced by the cooling apparatus 10 by 90 degrees from the original position shown in FIG. 8. Alternatively, when the check valve 60 of the cooling apparatus 10 has the configuration shown in FIG. 6, the information processing unit 100 can be operated in any position.

Thus, a desired long-term nonstop operation of the information processing unit 100 can be provided. In addition, the information processing unit 100 can be operated in any of various mounting positions.

While the present invention achieved by the inventors has been described above specifically in terms of its preferred embodiments, those skilled in the art should appreciate that the invention is not limited to the above-mentioned embodiments and various changes and modifications can be made in them without departing the spirit and scope thereof.

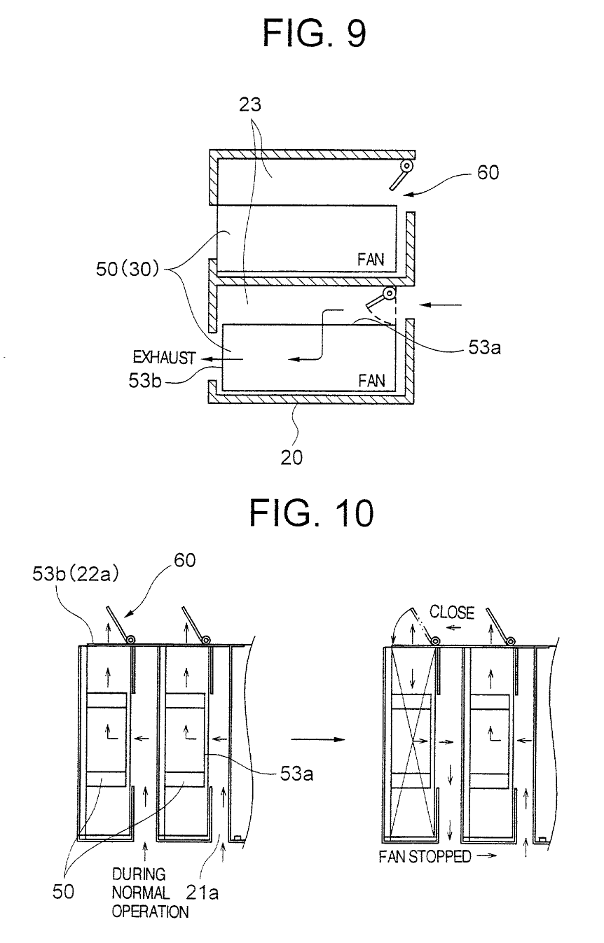

For example, the check valve 60 in the above-mentioned embodiment has been described, by way of example, for the case where it is located on the side of the outlet 22a but it may be located on the side of the inlet 21a as schematically shown in FIG. 9.

Also, the information processing unit 100 is not limited to the configuration as illustrated for the above-mentioned embodiment and it may have another configuration that, for example, only the plurality of fixed disk devices 102, 103 and the power module 108 to actuate them are mounted together with the cooling apparatus 10 within the housing 101. Alternatively, the information processing unit 100 may have still another configuration that, for example, only the plurality of I/O control modules 107 and the power module 108 to actuate them are mounted together with the cooling apparatus 10 within the housing 101.

Moreover, the information processing unit is not limited to the configuration as illustrated for the above-mentioned embodiment and the present invention may be applicable to a forced-air cooling technology used for an information processing unit of any configuration.

The cooling method according to the invention has the effect of suppressing a large reduction in cooling capacity due to any stopped multiblade fan in the collective arrangement of a plurality of multiblade fans operating continuously.

The cooling method according to the invention has the effect of allowing for replacement of any multiblade fan in a cooling apparatus having a plurality of multiblade fans operating continuously, without a large loss in cooling capacity of the cooling apparatus.

The cooling method according to the invention has the effect of allowing for replacement of any multiblade fan in a cooling apparatus having a plurality of multiblade fans operating continuously, irrespective of position of the cooling apparatus.

The cooling apparatus according to the invention has the effect of suppressing a large reduction in cooling capacity due to the stoppage of the specific multiblade fan in the collective arrangement of a plurality of multiblade fans operating continuously.

The cooling apparatus according to the invention has the effect of allowing for replacement of any multiblade fan in the cooling apparatus having a plurality of multiblade fans operating continuously, without any large loss in cooling capacity of the cooling apparatus.

The cooling apparatus according to the invention has the effect of allowing for replacement of any multiblade fan in the cooling apparatus having a plurality of multiblade fans operating continuously, irrespective of position of the cooling apparatus.

The information processing unit according to the invention has the effect of reducing in size of the whole housing including a cooling apparatus.

The information processing unit according to the invention has the effect of operating uninterruptedly irrespective of partial failure or maintenance of a cooling apparatus.

What is claimed is:

1. A method for cooling an information processing unit, comprising steps of:
arranging a plurality of fans in parallel at predetermined intervals in an axial direction of their rotors, each fan having its inlet and outlet opened in the axial direction and a circumferential direction of its rotor, respectively;
connecting said outlet with a partition which separates an inlet side from an outlet side of each fan;
providing a check valve in at least one of an inlet passage and an outlet passage for each fan to close said inlet passage or an outlet passage to autonomously prevent backflow of air from said outlet to said inlet when the fan stops operating; and
continuously operating said plurality of fans.

2. The cooling method according to claim 1, further comprising at least one of the following processes for autonomously preventing backflow of air from said output to said inlet:
a first process comprising steps of:
connecting a duct with said partition on an outlet side thereof; and
closing a valve element of said check valve corresponding to said stopped fan by means of an internal pressure in said duct to close said inlet or outlet passage,
a second process wherein a valve element of said check valve is closed by means of its own weight to close said inlet or outlet passage, and
a third process comprising steps of:
continuously exerting a force on a valve element of said check valve in a direction for closing said valve element;
opening said valve element against the closing force by means of a dynamic pressure in said inlet or outlet passage while said fan is operating; and
closing said valve element by the closing force when said fan stops operating to close said inlet or outlet passage.

3. A cooling apparatus for an information processing unit, comprising:
a plurality of fans arranged side by side in an axial direction of their rotors and continuously operated, each fan having its inlet and outlet opened in the axial and a circumferential direction of its rotor, respectively;
a check valve provided in at least one of an inlet passage and an outlet passage for each fan to close said inlet or outlet passage to autonomously prevent backflow of air from said outlet to said inlet when the fan stops operating; and
a partition separating an inlet side from an outlet side of each fan.

4. The cooling apparatus according to claim 3, further comprising at least one of the following configurations:
a first configuration having a duct connected with an outlet side of said partition,
wherein said check valve further comprises a valve element which moves freely within a rotary range of acute angle between an open position and a close position, and
wherein the valve element of said check valve corresponding to the stopped fan is closed by means of an internal pressure in said duct produced by the operating fans to close said inlet or outlet passage,
a second configuration wherein said check valve further comprises a valve element which moves freely within a rotary range of acute angle between an open position and a close position and said valve element of said check valve is closed by means of its own weight to close said inlet or outlet passage, and
a third configuration wherein said check valve further comprises:
a valve element moving freely between an open position and a close position; and
means for continuously exerting a force on said valve element in a direction for closing said valve element,
wherein said valve element is opened against the closing force by means of a dynamic pressure in said inlet or outlet passage while said fan is operating, and when said fan stops operating, said valve element is closed by the closing force to close said inlet or outlet passage.

5. A cooling apparatus comprising:
a fan box having a principal inlet side and a principal outlet side opposed to each other, in which sides a plurality of inlet openings and outlet openings are formed respectively;
a fan units attachable to/detachable from said fan box and each holding fans for continuous operation; and
check valves provided in at least one of said inlet openings and said outlet openings to autonomously prevent backflow of air from said outlet openings to said inlet openings when a fan stops operating.

6. The cooling apparatus according to claim 5, wherein said fan box comprises:
a terminal board provided at a position where said terminal board faces a side of each of said plurality of fan units which are attached to or detached from said fan box, said terminal board being connected with a feeding connector of said fan held in said fan unit; and
a suction duct provided in a space below said terminal board for communication between the inlet for said fan and the inlet opening in said principal inlet side.

7. The cooling apparatus according to claim 5 or 6, further comprising at least one of the following configurations:
a first configuration having a duct connected with an outlet side of said partition,
wherein said check valve further comprises a valve element which moves freely within a rotary range of acute angle between an open position and a close position, and
wherein the valve element of said check valve corresponding to the stopped fan is closed by means of an internal pressure in said duct produced by the operating fans to close said inlet or outlet opening;
a second configuration wherein said check valve further comprises a valve elements which move freely within a rotary range of acute angle between an open position and a close position and said valve element of said check valve is closed by means of its own weight to close said inlet or outlet opening; and
a third configuration wherein said check valve further comprises:
a valve element moving freely between an open position and a close position; and
means for continuously exerting a force on said valve element in a direction for closing said valve element,
wherein said valve element is opened against the closing force by means of a dynamic pressure of an inlet or outlet air flow while said fan is operating, and when said fan stops operating, said valve element is closed by the closing force to close said inlet or outlet opening.

8. An information processing unit having at least an external storage and a power supply mounted within a first housing, having in said first housing:
a cooling apparatus comprising:
a plurality of fans arranged in parallel in an axial direction of their rotors and continuously operated, each fan having its inlet and outlet opened respectively in the axial direction and a circumferential direction of its rotor;
a check valve provided in at least one of an inlet passage and an outlet passage for each fan for closing said inlet or outlet passage to autonomously prevent backflow of air from said outlet to said inlet when the fan stops operating; and
a partition separating an inlet side from an outlet side of the fan.

9. An information processing unit having at least an external storage and a power supply mounted within a first housing, having in said first housing:
a cooling apparatus comprising:
a fan box having a principal inlet side and a principal outlet side opposed to each other, in which sides a plurality of inlet openings and outlet openings are formed respectively;
fan units attachable to/detachable from said fan box and each holding fans continuously operating; and
a check valves provided in at least one of said inlet openings and said outlet openings to autonomously prevent backflow of air from said outlet openings to said inlet openings when a fan stops operating.

10. The information processing unit according to claim 8 or 9, further comprising in said first housing:
a central processing unit, a main storage, and said power supply on the outlet side of said cooling apparatus,
wherein said external storage is located on the inlet side of said cooling apparatus and a cooling duct, which guides exhaust flow branched from said cooling apparatus to said central processing unit, said main storage and said power supply, is located on the outlet side of said cooling apparatus with said cooling apparatus interposed between said external storage and said cooling duct.

11. A cooling apparatus for an electric device, comprising:
at least two or more fan units, each fan unit comprising:
two or more exhaust fans, each fan taking in gas through an inlet and discharging the gas through an outlet;
a gas flow check valve provided for each of said exhaust fans,
wherein said exhaust fans are disposed in parallel in a direction of a plane which includes said inlets for said exhaust fans and said check valves are disposed in either of gas passages associated with said exhaust fans; and
a fan box containing said fan units.

12. The cooling apparatus according to claim 11, wherein said fan box comprises:
a plurality of inlet openings in a principal inlet side;
a plurality of outlet openings in a principal outlet side opposed to said principal inlet side;
a terminal board provided at a location where said terminal board faces a side of each of said plurality of fan units which are attached to or detached from said fan box, said terminal block being connected with a feeding connector of the fan held in said fan unit; and
a suction duct provided in a space below said terminal board for communication between the inlet for said fan and the inlet opening in said principal inlet side.

13. The cooling apparatus according to claim 11 or 12, further comprising at least one of the following configurations:
a first configuration wherein said check valve further comprises a valve element which moves freely within a rotary range of acute angle between an open position and a close position, and
wherein said valve element of said check valve corresponding to a stopped, specific fan is closed by means of an internal pressure produced by the operating fans to close said inlet or outlet opening;
a second configuration wherein said check valve further comprises a valve element which moves freely within a rotary range of acute angle between an open position and a close position and said valve element of said check valve is closed by means of its own weight to close said inlet or outlet opening; and
a third configuration wherein said check valve further comprises:
a valve element moving freely between an open position and a close position; and
means for continuously exerting a force on said valve element in a direction for closing said valve element,
wherein said valve element is opened against the closing force by means of a dynamic pressure of an inlet or outlet air flow while said fan is operating, and when said fan stops operating, said valve element is closed by the closing force to close said inlet or outlet opening.

14. An electric device having at least an external storage and a power supply mounted within a first housing, having in said first housing:
a cooling apparatus comprising:
at least two or more fan units, each fan unit comprising:
two or more exhaust fans, each fan taking in gas through an inlet and discharging the gas through an outlet; and
a gas flow check valve provided for each of said outlet fans,
wherein said exhaust fans are disposed in parallel in a direction of a plane which includes said inlets for said exhaust fans, and said check valves are disposed in either of gas passages associated with said exhaust fans; and
a fan box containing said fan units.

15. The electric device according to claim 14, wherein said fan box comprises:
a plurality of inlet openings in a principal inlet side;
a plurality of outlet openings in a principal outlet side opposed to said principal inlet side;
a terminal board provided at a location where said terminal board faces a side of each of said plurality of fan units which are attached to or detached from said fan box, said terminal board being connected with a feeding connector of the fan held in said fan unit; and
a suction duct provided in a space below said terminal board for communication between the inlet for said fan and the inlet opening in said principal inlet side.

16. The electric device according to claim 14 or 15, wherein said cooling apparatus further comprise at least one of the following configurations:
a first configuration wherein said check valve further comprises a valve element which moves freely within a rotary range of acute angle between an open position and a close position,
wherein said valve element of said check valve corresponding to a stopped, specific fan is closed by means of an internal pressure produced by the operating fans to close said inlet or outlet opening;
a second configuration wherein said check valve further comprises a valve element which moves freely within a rotary range of acute angle between an open position and a close position and said valve element of said check valve is closed by means of its own weight to close said inlet or outlet opening; and
a third configuration wherein said check valve further comprises:
a valve element moving freely between an open position and a close position; and
means for continuously exerting a force on said valve element in a direction for closing said valve element,
wherein said valve element is opened against the closing force by means of a dynamic pressure in said inlet or outlet opening while the associated fan is operating, and when said fan stops operating, said valve element is closed by the closing force to close said inlet or outlet opening.
